(19) United States
(12) Patent Application Publication
(10) Pub. No.: US 2012/0211067 A1
(43) Pub. Date: Aug. 23, 2012

(54) PHOTOELECTRIC CONVERSION DEVICE

(75) Inventors: Shunpei YAMAZAKI, Tokyo (JP); Fumito Isaka, Zama (JP); Jiro Nishida, Atsugi (JP)

(73) Assignee: SEMICONDUCTOR ENERGY LABORATORY CO., LTD., Atsugi-shi (JP)

(21) Appl. No.: 13/398,876

(22) Filed: Feb. 17, 2012

(30) Foreign Application Priority Data
Feb. 21, 2011 (JP) 2011-034576

(51) Int. Cl. H01L 31/036; H01L 31/0236; H01L 31/06; H01L 31/02

(52) U.S. Cl. 136/255; 136/252; 136/258; 136/256

(57) ABSTRACT

A photoelectric conversion device in which photoelectric conversion in a light-absorption layer is efficiently performed is provided. In the photoelectric conversion device, a light-transmitting conductive film which has a high effect of passivation of defects on a silicon surface and improves the reflectance on a back electrode side is provided between the back electrode and one of semiconductor layers for generation of an internal electric field. The light-transmitting conductive film includes an organic compound and an inorganic compound. The organic compound includes a material having an excellent hole-transport property. The inorganic compound includes a transition metal oxide having an electron-accepting property.

### BACKGROUND OF THE INVENTION

1. Field of the Invention

The present invention relates to a photoelectric conversion device including a light-transmitting conductive film with which the reflectance on a back electrode side is improved.

2. Description of the Related Art

In recent years, a photoelectric conversion device that generates power without carbon dioxide emissions has attracted attention as a countermeasure against global warming. Typical examples thereof are a bulk type solar cell including a crystalline silicon substrate of single crystal silicon, polycrystalline silicon, or the like, and a thin-film type solar cell including a thin film of amorphous silicon, microcrystalline silicon, or the like.

A thin-film type solar cell includes a thin film which is formed using a required amount of silicon by a plasma CVD method or the like; thus, resource saving can be achieved as compared to the case of a bulk type solar cell. In addition, an integrated thin film solar cell can be easily formed using, a laser processing method, a screen printing method, or the like, and an increase in area of the thin film solar cell can be easily achieved; therefore, the production cost thereof can be reduced. However, a thin-film type solar cell has a disadvantage in that the conversion efficiency thereof is lower than that of a bulk type solar cell.

In order to improve the conversion efficiency of the thin-film type solar cell (hereinafter, referred to as thin film solar cell), a method in which silicon oxide is used instead of silicon for a p layer serving as a window layer has been disclosed (for example, see Patent Document 1). A thin film of non-single-crystal silicon based p layer has light-absorption properties almost equivalent to those of an i layer serving as a light-absorption layer; therefore, light absorption loss occurs. Patent Document 1 discloses a technique in which silicon oxide having a larger optical band gap than silicon is used for a p layer in order to suppress light absorption by a window layer.

### REFERENCE

### Patent Document

[Patent Document 1] Japanese Published Patent Application No. H07-130661

### SUMMARY OF THE INVENTION

However, even in the case where light absorption loss by the window layer does not occur at all, the electric characteristics of the thin film solar cell cannot be improved unless the light-absorption layer efficiently absorbs light.

As a method for improving light-absorption properties of a light-absorption layer of a thin film solar cell, a method in which the thickness of the light-absorption layer is made large and the optical path length is lengthened is given. For example, in the case of a p-i-n-type thin film solar cell including an amorphous silicon thin film, the thickness of an i-type amorphous silicon layer may be large.

However, when the thickness of the light-absorption layer is too large, an internal electric field applied to the light-absorption layer is reduced and the absolute quantity of defects in the light-absorption layer is increased; therefore, carriers are easily recombined in the light-absorption layer, and the fill factor is decreased. That is, since the thickness of the light-absorption layer needs to be in an appropriate range, a method is desired in which photoelectric conversion is efficiently performed in the light-absorption layer whose thickness is in such an appropriate range.

Therefore, an object of one embodiment of the present invention is to provide a photoelectric conversion device in which the optical path length in a light-absorption layer can be lengthened and photoelectric conversion can be efficiently performed.

One embodiment of the present invention disclosed in this specification relates to a photoelectric conversion device including a light-transmitting conductive film (also referred to as a light-transmitting film) which includes an organic compound and an inorganic compound and with which the reflectance on a back electrode side is improved.

One embodiment of the present invention disclosed in this specification is a photoelectric conversion device including, between a pair of electrodes, a first silicon semiconductor layer; a second silicon semiconductor layer in contact with the first silicon semiconductor layer; a third silicon semiconductor layer in contact with the second silicon semiconductor layer; and a light-transmitting conductive film in contact with the third silicon semiconductor layer. The light-transmitting conductive film includes an organic compound and an inorganic compound.

Note that in this specification and the like, ordinal numbers such as “first” and “second” are used in order to avoid confusion among components, and do not limit the order or number of the components.

The first silicon semiconductor layer has p-type conductivity, the second silicon semiconductor layer has i-type conductivity, and the third silicon semiconductor layer has n-type conductivity.

The second silicon semiconductor layer is preferably non-single-crystal, amorphous, microcrystalline, or polycrystalline.

Another embodiment of the present invention disclosed in this specification is a photoelectric conversion device including, between a pair of electrodes, a first silicon semiconductor layer; a second silicon semiconductor layer in contact with the first silicon semiconductor layer; a third silicon semiconductor layer in contact with the second silicon semiconductor layer; a first light-transmitting conductive film in contact with the third silicon semiconductor layer; a fourth silicon semiconductor layer in contact with the first light-transmitting conductive film; a fifth silicon semiconductor layer in contact with the fourth silicon semiconductor layer; a sixth silicon semiconductor layer in contact with the fifth silicon semiconductor layer; and a second light-transmitting conductive film in contact with the sixth silicon semiconductor layer. The second light-transmitting conductive film includes an organic compound and an inorganic compound.

The first silicon semiconductor layer and the fourth silicon semiconductor layer have p-type conductivity, the second silicon semiconductor layer and the fifth silicon semiconductor layer have i-type conductivity, and the third silicon semiconductor layer and the sixth silicon semiconductor layer have n-type conductivity.

The second silicon semiconductor layer is preferably amorphous, and the fourth silicon semiconductor layer is preferably microcrystalline or polycrystalline.

In the photoelectric conversion device according to one embodiment of the present invention, an oxide of a metal belonging to any of Groups 4 to 8 of the periodic table can be used as the inorganic compound. Specifically, vanadium oxide, niobium oxide, tantalum oxide, chromium oxide, molybdenum oxide, tungsten oxide; manganese oxide, rhenium oxide, or the like can be used.

As the organic compound, any of an aromatic amine compound, a carbazole derivative, an aromatic hydrocarbon, a high molecular compound, and a heterocyclic compound having a dibenzofuran skeleton or a dibenzothiophene skeleton can be used.

According to one embodiment of the present invention, a photoelectric conversion device in which a substantial optical path length in a light-absorption layer can be lengthened and which has high conversion efficiency can be provided.

### BRIEF DESCRIPTION OF THE DRAWINGS

FIG. 1 is a cross-sectional view illustrating a photoelectric conversion device according to one embodiment of the present invention.

FIG. 2 is a cross-sectional view illustrating a photoelectric conversion device according to one embodiment of the present invention.

FIG. 3 is a cross-sectional view illustrating a photoelectric conversion device according to one embodiment of the present invention.

FIGS. 4A to 4D are cross-sectional views illustrating a process of a manufacturing method of a photoelectric conversion device according to one embodiment of the present invention.

FIG. 5 shows a calculation model of reflectance.

FIG. 6 shows calculation results of reflectance.

FIG. 7 shows calculation results of reflectance.

FIG. 8 shows spectral transmittance of a light-transmitting conductive film and spectral sensitivity characteristics of an amorphous silicon photoelectric conversion device.

### DETAILED DESCRIPTION OF THE INVENTION

Hereinafter, embodiments of the present invention will be described in detail with reference to the accompanying drawings. Note that the present invention is not limited to the description below, and it is easily understood by those skilled in the art that modes and details disclosed herein can be modified in various ways. Therefore, the present invention is not construed as being limited to description of the embodiments below. Note that in all drawings used to illustrate the embodiments, portions that are identical or portions having similar functions are denoted by the same reference numerals, and their repetitive description may be omitted.

### Embodiment 1

In this embodiment, a photoelectric conversion device according to one embodiment of the present invention, and a manufacturing method thereof will be described.

In a photoelectric conversion device according to one embodiment of the present invention, a light-transmitting conductive film including a composite material of an inorganic compound and an organic compound each having an excellent light-transmitting property is provided between a back electrode and one of semiconductor layers for generation of an internal electric field. By providing the light-transmitting conductive film, an interface having high birefringence is generated between the light-transmitting conductive film and the back electrode; thus, the reflectance can be improved. Therefore, a substantial optical path length in a light-absorption layer of the photoelectric conversion device can be lengthened.

Since the light-transmitting conductive film has a high passivation effect, a defect is less likely to be generated at the interface with the semiconductor layer and recombination of photo-induced carriers can be prevented. By such effects, a photoelectric conversion device with high conversion efficiency can be manufactured.

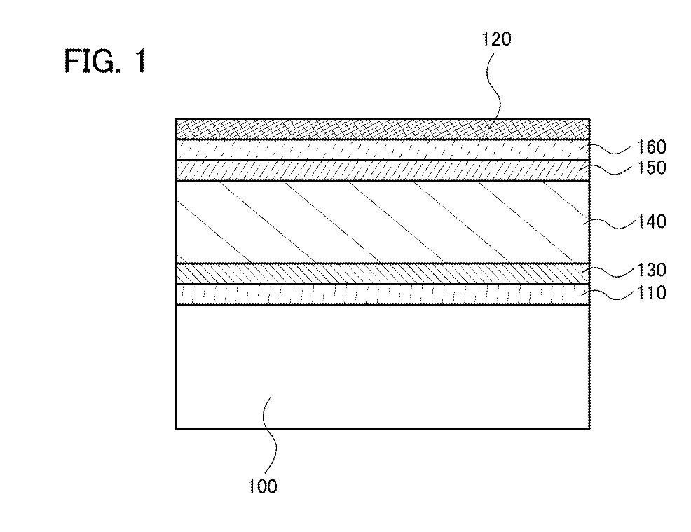

FIG. 1 is a cross-sectional view of a photoelectric conversion device according to one embodiment of the present invention, which includes a first electrode 110, a first silicon semiconductor layer 130, a second silicon semiconductor layer 140, a third silicon semiconductor layer 150, a light-transmitting conductive film 160, and a second electrode 120 stacked in this order over a substrate 100. Note that in the photoelectric conversion device of FIG. 1, a side on which the substrate 100 is provided serves as a light-receiving surface; however, the opposite side to the substrate 100 may serve as a light-receiving surface by reversing the order of stacking the layers over the substrate 100.

For the substrate 100, a glass substrate of general flat glass, clear flat glass, lead glass, or crystallized glass can be used, for example. Alternatively, a non-alkali glass substrate of aluminosilicate glass, barium borosilicate glass, aluminoborosilicate glass, or the like, or a quartz substrate can be used. In this embodiment, a glass substrate is used as the substrate 100.

Alternatively, a resin substrate can be used as the substrate 100. For example, the following are given: polyether sulfone (PES); polyethylene terephthalate (PET); polyethylene naphthalate (PEN); polycarbonate (PC); a polyamide-based synthetic fiber; polyether etherketone (PEEK); polysulfone (PSF); polyether imide (PEI); polyarylate (PAR); polybutylene terephthalate (PBT); polyimide; an acrylonitrile butadiene styrene resin; poly vinyl chloride; polypropylene; poly vinyl acetate; an acrylic resin; and the like.

For the first electrode 110, a light-transmitting conductive film containing the following can be used: indium tin oxide; indium tin oxide containing silicon; indium oxide containing zinc; zinc oxide; zinc oxide containing gallium; zinc oxide containing aluminum; tin oxide; tin oxide containing fluorine; tin oxide containing antimony; or the like. The above light-transmitting conductive film is not limited to a single layer, and may be a stacked layer of different films. For example, a stacked layer of indium tin oxide and zinc oxide containing aluminum, a stacked layer of indium tin oxide and tin oxide containing fluorine, or the like can be used. The total thickness is greater than or equal to 10 nm and less than or equal to 1000 nm.

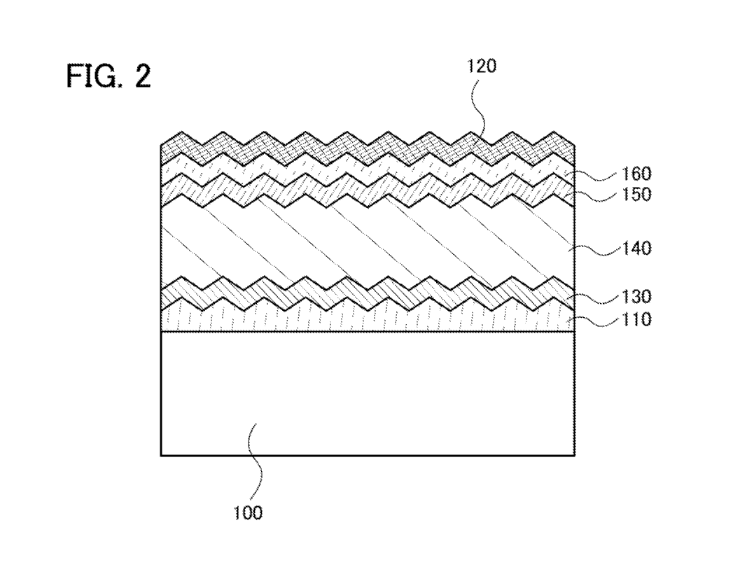

Alternatively, as illustrated in FIG. 2, a surface of the first electrode 110 may be uneven. By making the surface of the first electrode 110 uneven, each interface of layers stacked thereover also becomes uneven. Due to the uneven surface and interfaces, multiple reflection from a surface of the substrate; an increase in optical path length in a photoelectric conversion layer, and a total reflection effect (light-trapping effect) in which light reflected by a back electrode side is totally reflected by the surfaces and interfaces are achieved, and electric characteristics of the photoelectric conversion device can be improved.

A p-type silicon semiconductor film is used for the first silicon semiconductor layer 130. The first silicon semiconductor layer 130 preferably has a thickness greater than or equal to 1 nm and less; than or equal to 50 nm. Further, although amorphous silicon can be used for the first silicon semiconductor layer 130, it is preferable to use microcrystalline silicon or polycrystalline silicon which has lower resistance.

An i-type silicon semiconductor film is used for the second silicon semiconductor layer 140. Note that in this specification, an “i-type semiconductor” refers not only to a so-called intrinsic semiconductor in which the Fermi level lies in the middle of the band gap, but also to a semiconductor in which the concentration of an impurity imparting p-type or n-type conductivity is 1×10²⁰ cm⁻³ or less, and in which the photoconductivity is 100 times or more as high as the dark conductivity. This i-type silicon semiconductor may include an element belonging to Group 13 or Group 15 of the periodic table as an impurity.

Non-single-crystal silicon, amorphous silicon, microcrystalline silicon, or polycrystalline silicon is preferably used as an i-type silicon semiconductor film used for the second silicon semiconductor layer 140. Amorphous silicon has a peak of spectral sensitivity in the visible light region; thus, a photoelectric conversion device having a high photoelectric conversion ability in an environment with low illuminance, for example, under a fluorescent lamp can be formed. Microcrystalline silicon and polycrystalline silicon have a peak of spectral sensitivity in a longer wavelength range than the visible light region; thus, a photoelectric conversion device having a high photoelectric conversion ability in an outdoor environment where solar light is used as a light source can be manufactured, in the case where amorphous silicon is used for the second silicon semiconductor layer 140, the thickness thereof is preferably greater than or equal to 100 nm and less than or equal to 600 nm. In the case where microcrystalline silicon or polycrystalline silicon is used for the second silicon semiconductor layer 140, the thickness thereof is preferably greater than or equal to 1 μm and less than or equal to 100 μm.

An n-type silicon semiconductor film is used for the third silicon semiconductor layer 150. The third silicon semiconductor layer 150 preferably has a thickness greater than or equal to 1 nm and less than or equal to 50 nm. Further, although amorphous silicon can be used for the third silicon semiconductor layer 150, it is preferable to use microcrystalline silicon or polycrystalline silicon which has lower resistance.

The p-type first silicon semiconductor layer 130, the i-type second silicon semiconductor layer 140, and the n-type third silicon semiconductor layer 150 described above are stacked, whereby a p-i-n junction can be formed.

The light-transmitting conductive film 160 is formed using a composite material of an inorganic compound and an organic compound. As the inorganic compound, a transition metal oxide can be used; in particular, an oxide of a metal belonging to any of Groups 4 to 8 of the periodic table is preferable. Specifically, vanadium oxide, niobium oxide, tantalum oxide, chromium oxide, molybdenum oxide, tungsten oxide, manganese oxide, rhenium oxide, or the like can be used. Among these, molybdenum oxide is especially preferable since it is stable in the air, has a low hygroscopic property, and is easily handled.

As the organic compound, any of a variety of compounds such as an aromatic amine compound, a carbazole derivative, an aromatic hydrocarbon, a high molecular compound (e.g., an oligomer, a dendrimer, or a polymer), and a heterocyclic compound having a dibenzofuran skeleton or a dibenzothiophene skeleton can be used. As the organic compound used for the composite material, an organic compound having an excellent hole-transport property is used. Specifically, a substance having a hole mobility of 10⁻⁶ cm²/Vs or higher is preferably used. However, any other substance that has a property of transporting more holes than electrons may be used.

The transition metal oxide has an electron-accepting property; when it is used in combination with an organic coin pound having an excellent hole-transport property, a composite material thereof has high carrier density and exhibits conductivity. The composite material has high transmittance of light in a wide wavelength range from visible light region to infrared region.

The composite material is stable, and silicon oxide is not generated at an interface with a silicon film; thus, defects at the interface can be reduced, resulting in improvement in lifetime of carriers.

In the case where the composite material is formed as a passivation film over an n-type; single crystal silicon substrate, the following has been con finned by the experiment: the lifetime of carriers is 700 μsec or more when 4-phenyl-4′-(9-phenylfluoren-9-yl)triphenylamine (abbreviation: BPAFLP) and molybdenum(VI) oxide are used as the organic compound and the inorganic compound respectively; the lifetime of carriers is 400 μsec or more when 4,4′-bis[N-(1-naphthyl)-N-phenylamino]biphenyl (abbreviation: NPB) and molybdenum(VI) oxide are used as the organic compound and the inorganic compound respectively. Note that the lifetime of carriers in the case where a passivation film is hot formed over an n-type single crystal silicon substrate is about 40 μsec, and the lifetime of carriers in the case where indium tin oxide (ITO) is formed on both of surfaces of the single crystal silicon substrate by a sputtering method is about 30 μsec.

For the second electrode 120, a metal film of aluminum, titanium, nickel, silver, molybdenum, tantalum, tungsten, chromium, copper, stainless steel, or the like can be used. The metal film is not limited to a single layer, and may be a stacked layer of different films. For example, a stacked layer of stainless steel and aluminum, a stacked layer of silver and aluminum, or the like can be used. The total thickness is greater than or equal to 100 nm and less than or equal to 600 nm, preferably greater than or equal to 100 nm and less than or equal to 300 nm.

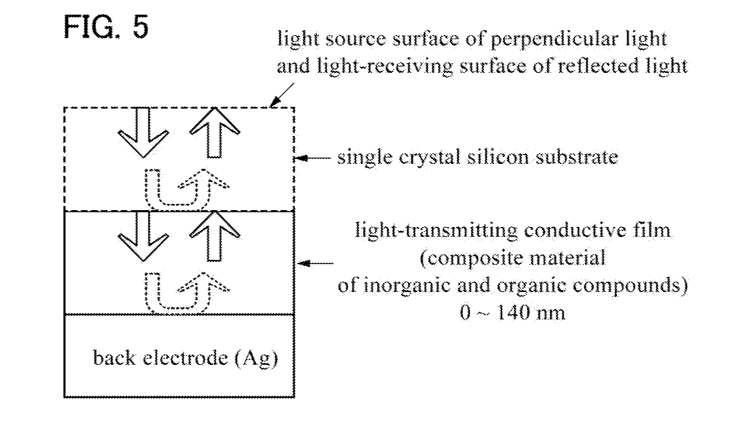

Next, calculation results of reflectance in the vicinity of a back electrode (the second electrode 120 in the structure of FIG. 1) will be described. FIG. 5 shows a calculation model, in which silver as the back electrode, the light-transmitting conductive film (the composite material of BPAFLP and molybdenum(VI) oxide), and the single crystal silicon substrate are stacked. Light is emitted perpendicularly to the back electrode, and the surface of the single crystal silicon substrate serves as a light source surface and as a light-receiving surface of reflected light.

At this time, it is assumed that the thickness of the single crystal silicon substrate is extremely small, and light absorption therein is not taken into consideration. Therefore, the calculation results are not largely changed depending on whether any of amorphous silicon, microcrystalline silicon, and polycrystalline silicon is used. Further, BPAFLP is used for the material of the light-transmitting conductive film as one example; however, even in the case where another organic material is used, the calculation results are not largely changed as long as the refractive index (n) and the extinction coefficient (k) are approximate to those of BPAFLP.

Optical simulation software, “DiffractMOD” (produced by RSoft Design Group, Inc.) was used for the calculation, and the reflectances of light having a wavelength of 500 nm to 1200 nm in the case where the thickness of the light-transmitting conductive film is changed from 0 nm to 140 nm in increments of 10 nm were calculated. Note that the reflectance of light having a wavelength shorter than 500 nm was not calculated because such light is largely absorbed by a silicon thin film and the amount of such light arriving at the back surface is negligible. Table 1 shows values of the refractive index (n) and the extinction coefficient (k) of each material, which were calculated at typical wavelengths. Note that the actual calculation was performed under the condition where the wavelength was changed in increments of 20 nm.

TABLE 1

| | | | Light-transmitting | | | |
|---|---|---|---|---|---|---|
| | | | Conductive Film (Composite | | | |
| | | | Material of BPAFLP and | | | |
| | Single Crystal Silicon | | Molybdenum Oxide) | | Back Electrode (Silver) | |
| Wavelength/nm | n | k | n | k | n | k |
| 500 | 4.31E+00 | 7.26E−02 | 1.75E+00 | 5.00E−03 | 1.30E−01 | 2.91E+00 |
| 600 | 3.95E+00 | 2.69E−02 | 1.70E+00 | 1.80E−02 | 1.24E−01 | 3.72E+00 |
| 700 | 3.79E+00 | 1.27E−02 | 1.68E+00 | 3.00E−02 | 1.42E−01 | 4.51E+00 |
| 800 | 3.69E+00 | 6.48E−03 | 1.70E+00 | 5.90E−02 | 1.44E−01 | 5.28E+00 |
| 900 | 3.63E+00 | 2.62E−03 | 1.74E+00 | 5.10E−02 | 1.68E−01 | 6.02E+00 |
| 1000 | 3.58E+00 | 6.98E−04 | 1.71E+00 | 2.80E−02 | 2.13E−01 | 6.65E+00 |
| 1100 | 3.55E+00 | 1.41E−04 | 1.70E+00 | 2.10E−02 | 2.42E−01 | 7.16E+00 |
| 1200 | 3.52E+00 | 0.00E+00 | 1.70E+00 | 1.40E−02 | 3.02E−01 | 7.64E+00 |

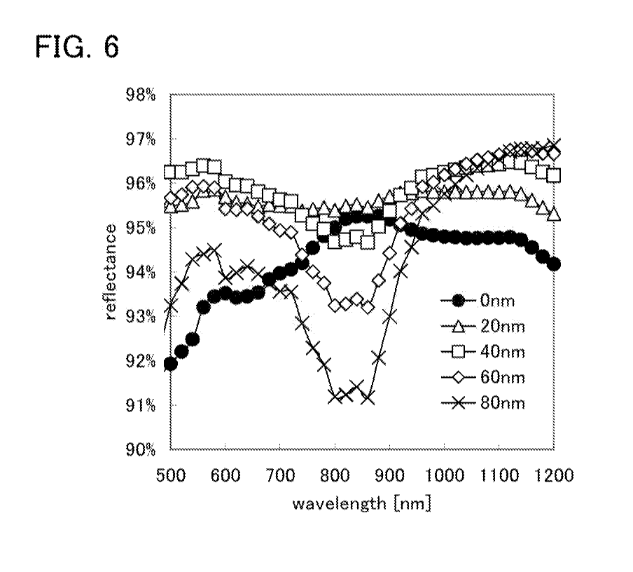

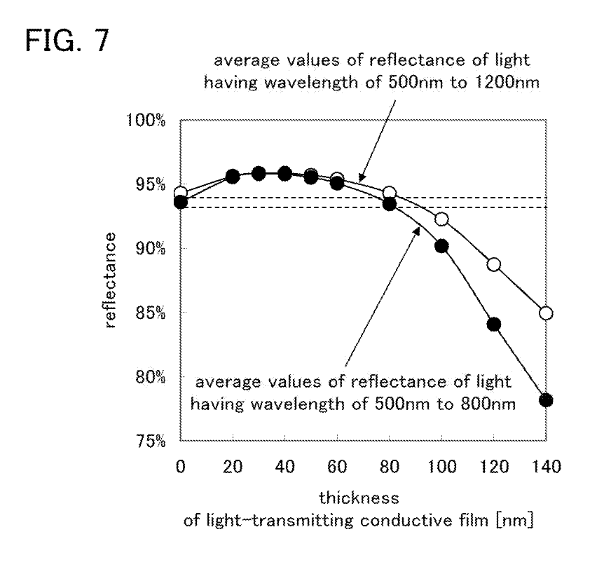

FIG. 6 shows calculation results of the reflectance under the above conditions. For the sake of clarity of the graph, only the calculation results obtained when the thickness of the light-transmitting conductive film is 0 nm, 20 nm, 40 nm, 60 nm, and 80 nm are shown. FIG. 7 shows the average values of reflectance with respect to the thicknesses, which are obtained from the calculation results. White circles in the graph represent average values of reflectance of light, having, a wavelength of 500 nm to 1200 nm. Black circles in the graph represent average values of reflectance of light having a wavelength of 500 nm to 800 nm. Since the spectral sensitivity varies depending on the material of a light-absorption layer (the second silicon semiconductor layer 140 in the structure of FIG. 1), the average values of reflectance obtained when the wavelength is in the range of 500 nm to 1200 nm may be used in the case where microcrystalline silicon, or polycrystalline silicon is used, for the light-absorption layer, and those obtained when the wavelength is in the range of 500 nm to 800 nm may be used in the case where amorphous silicon is used for the light-absorption layer.

These results indicate that, for improvement in reflectance on the back surface side, the thickness of the light-transmitting conductive film is preferably greater than 0 nm and less than 80 nm, further preferably greater than or equal to 20 nm and less than or equal to 60 nm, still further preferably greater than or equal to 20 nm and less than or equal to 50 nm.

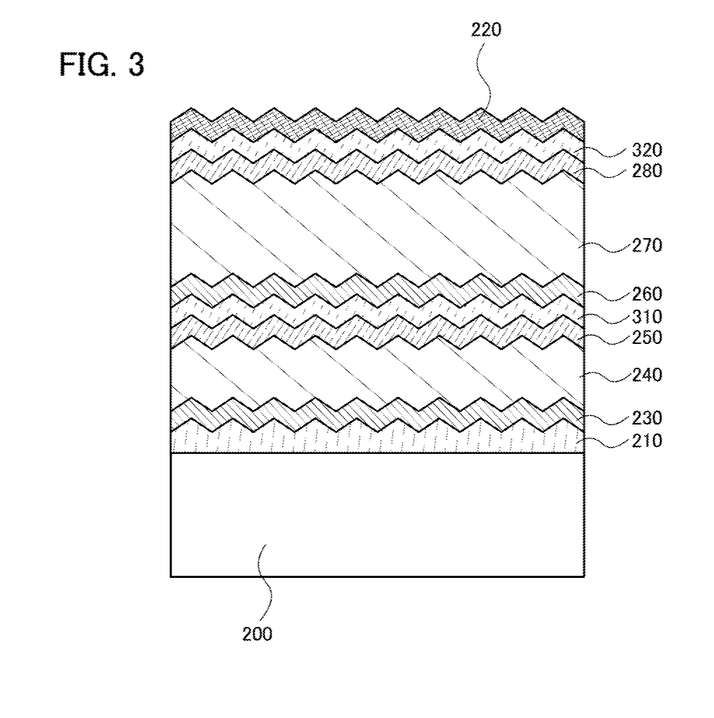

Note that a photoelectric conversion device according to one embodiment of the present invention may have a structure illustrated in FIG. 3, in which a first electrode 210, a first silicon semiconductor layer 230, a second silicon semiconductor layer 240, a third silicon semiconductor layer 250, a first light-transmitting conductive film 310, a fourth silicon semiconductor layer 260, a fifth silicon semiconductor layer 270, a sixth silicon semiconductor layer 280, a second light-transmitting conductive film 320, and a second electrode 220 are provided over a substrate 200. A photoelectric conversion device having such a structure is a so-called tandem photoelectric conversion device where a top cell in which the second silicon semiconductor layer 240 serves as a light-absorption layer and a bottom cell in which the fifth silicon semiconductor layer 270 serves as a light-absorption layer are connected in series.

In the photoelectric conversion device of FIG. 3, amorphous silicon is used for the second silicon semiconductor layer 240, and microcrystalline silicon or polycrystalline silicon is used for the fifth silicon semiconductor layer 270. The first silicon semiconductor layer 230 and the fourth silicon semiconductor layer 260 can be formed using the same material as the first silicon semiconductor layer 130 described above, and the third silicon semiconductor layer 250 and the sixth silicon semiconductor layer 280 can be formed using the same material as the third silicon semiconductor layer 150 described above. The first electrode 210 and the first light-transmitting conductive film 310 can be formed using the same material as the first electrode 110 described above, and the second light-transmitting conductive film can be formed using the same material as the light-transmitting conductive film 160 described above. The second electrode 220 can be formed using the same material as the second electrode 120 described above.

Light which has entered the top cell through the first electrode 210 from the substrate 100 side and whose wavelength is shorter than that of visible light is mainly converted into electric energy in the second silicon semiconductor layer 240, and light which has passed through the top cell and whose wavelength is longer than that of visible light is mainly converted into electric energy in the fifth silicon semiconductor layer 270. Therefore, light with a wide wavelength range can be effectively utilized, and the conversion efficiency of the photoelectric conversion device can be improved.

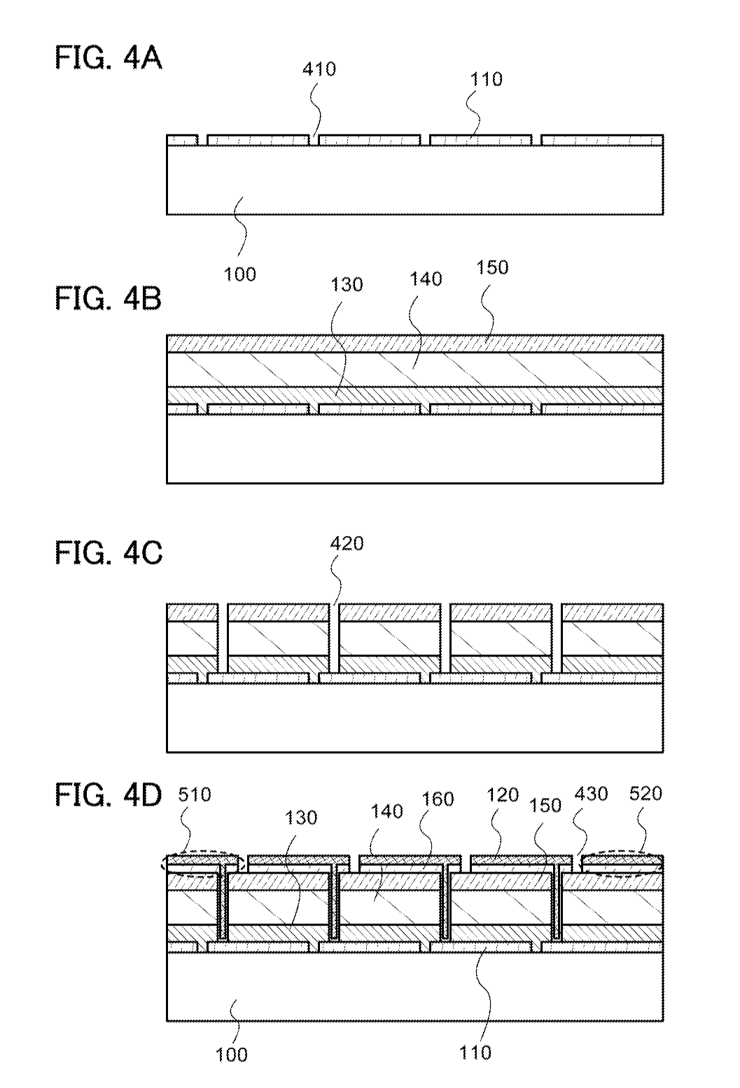

Next, a manufacturing method of a photoelectric conversion device according to one embodiment of the present invention will be described with reference to FIGS. 4A to 4D. A description will be given below of a manufacturing method of ah integrated photoelectric conversion device in which a plurality of photoelectric conversion devices in FIG. 1 is connected in series. A completed structure thereof is illustrated in FIG. 4D.

First, a light-transmitting conductive film serving as the first electrode 110 is formed over the substrate 100. Here, an indium tin oxide (ITO) film with a film thickness of 100 nm is formed by a sputtering method. Note that the surface of the light-transmitting conductive film can be easily made uneven as illustrated in FIG. 2 by etching, for example, a zinc oxide-based light-transmitting conductive film with the use of strong acid such as hydrochloric acid.

A glass substrate is used as the substrate 100 in this embodiment; when a resin substrate with a thickness of, for example, about 100 μm is used, roll-to-roll processing can be performed.

In roll-to-roll processing, in addition to a film formation step by a sputtering method, a plasma CVD method, or the like, a step by a screen printing method, a laser processing method, or the like is also included. Accordingly, almost the entire manufacturing process of a photoelectric conversion device can be performed by roll-to-roll processing. Alternatively, the process may partially be performed by roll-to-roll processing, the object produced by the roll-to-roll processing may be divided into sheet forms, and the latter steps may be performed individually for each sheet. For example, by attaching each piece of the divided sheet to a frame that is formed of ceramic, metal, a composite body thereof, or the like, it can be handled in the same manner as a glass substrate or the like.

Next, a first separation groove 410 which separates the light-transmitting conductive film into a plurality of; pieces is formed (see FIG. 4A). The separation groove can be formed by laser processing or the like. As a laser used in this laser processing, a continuous wave laser or a pulsed laser which emits light in the visible light region or the infrared light region is preferably used. For example, the fundamental wave (wavelength: 1064 nm) or the second harmonic (wavelength: 532 nm) of an Nd-YAG laser can be used. Note that here, a portion of the separation groove may reach the substrate 100. Also, by the light-transmitting conductive film getting separated in this step, the first electrode 110 is formed.

Next, as the first silicon semiconductor layer 130, a p-type microcrystalline silicon film of 30 nm thick is formed by a plasma CVD method. In this embodiment, a doping gas containing an impurity imparting p-type conductivity is mixed into a source gas, and a p-type microcrystalline silicon film is formed by a plasma CVD method. As the impurity imparting p-type conductivity, an element belonging to Group 13 of the periodic; table such as boron or aluminum can typically be given. For example, a doping gas such as diborane is mixed into a source gas such as silane, so that a p-type microcrystalline silicon film can be formed. Note that although the first silicon semiconductor layer 130 may be formed using amorphous silicon, it is preferably formed using microcrystalline silicon which has lower resistance.

Then, as the second silicon semiconductor layer 140, an i-type amorphous silicon film of 600 nm thick is formed. As a source gas, silane or disilane can be used, and hydrogen may be added thereto. At this time, an atmospheric component contained in the film serves as a donor in some cases; thus, boron (B) may be added to the source gas so that the conductivity type is closer to i-type. In this case, the concentration of boron in the i-type amorphous silicon is made to be higher than or equal to 0.001 at. % and lower than or equal to 0.1 at. %.

Next, as the third silicon semiconductor layer 150, an n-type microcrystalline silicon film of 30 nm thick is formed (see FIG. 4B). In this embodiment, a doping gas containing an impurity imparting n-type conductivity is mixed into a source gas, and ah n-type microcrystalline silicon film is formed by a plasma CVD method. As the impurity imparting n-type conductivity, an element belonging to Group 15 of the periodic table such as phosphorus, arsenic, or antimony can typically be given. For example, a doping gas such as phosphine is mixed into a source gas such as silane, so that an n-type microcrystalline silicon film can be formed. Note that although the third silicon semiconductor layer 150 may be formed using amorphous silicon, it is preferably formed using microcrystalline silicon which has lower resistance.

Then, a second separation groove 420 which separates a stacked layer of the first silicon semiconductor layer 130, the second silicon semiconductor layer 140, and the third silicon semiconductor layer 150 into a plurality of pieces is formed (see FIG. 4C). This separation groove can be formed by laser processing or the like. As a laser used in this laser processing, a continuous wave laser or a pulsed laser which emits light in the visible light region is preferably used. For example, the second harmonic (wave length: 532 nm) or the like of an Nd-YAG laser can be used.

Next, the light-transmitting conductive film 160 is formed so as to cover the second separation groove 420 and the third silicon semiconductor layer 150. The light-transmitting conductive film 160 is formed by a co-evaporation method using the above-described inorganic compound and organic compound. A co-evaporation method is an evaporation method in which evaporation is concurrently carried out from a plurality of evaporation sources in one treatment chamber. It is preferable that deposition be performed in high vacuum. The high vacuum can be obtained by evacuation of a deposition chamber with an evacuation unit to a vacuum of about 5×10⁻³ Pa or less, preferably about 10⁻⁴ Pa to 10⁻⁶ Pa.

In this embodiment, the light-transmitting conductive film 160 is formed by co-evaporating 4-phenyl-4′-(9-phenylfluoren-9-yl)triphenylamine (abbreviation: BPAFLP) and molybdenum(VI) oxide. The thickness of the light-transmitting conductive film 160 is 50 nm, and the weight ratio of BPAFLP to molybdenum oxide is controlled to be 2:1 (=BPAFLP:molybdenum oxide).

Then, a conductive film is formed over the light-transmitting conductive film 160. Here, a 5-nm-thick silver film and a 300-nm-thick aluminum film are sequentially stacked by a sputtering method.

Then, a third separation groove 430 which separates the conductive film into a plurality of pieces is formed (see FIG. 4D). The separation groove can be formed by laser processing or the like. As a laser used in this laser processing, a continuous wave laser or a pulsed laser which emits light in the infrared light region is preferably used. For example, the fundamental wave (wavelength: 1064 nm) or the like of an Nd-YAG laser can be used. In this step, the conductive film is processed to be separated, whereby the second electrode 120, a first terminal 510, and a second terminal 520 are formed. Here, the first terminal 510 and the second terminal 520 serve as extraction electrodes.

Through the above process, the photoelectric conversion device according to one embodiment of the present invention can be manufactured. Note that although a description is given of the manufacturing method of the structure in which the photoelectric conversion device in FIG. 1 is integrated in this embodiment, the photoelectric conversion devices in FIG. 2 and FIG. 3 can be integrated in a similar manner.

This embodiment can be implemented in combination with any of the structures described in another embodiment as appropriate.

### Embodiment 2

In this embodiment, the light-transmitting conductive film described in Embodiment 1 will be described.

As the light-transmitting conductive film used as a reflection layer of the photoelectric conversion device described in Embodiment 1, a composite material of a transition metal oxide and an organic compound can be used. Note that in this specification, the word “composite” means not only a state in which two materials are simply mixed but also a state in which a plurality of materials is mixed and charges are transferred between the materials.

As the transition metal oxide, a transition metal oxide having an electron-accepting property can be used. Specifically, among transition metal oxides, an oxide of a metal belonging to any of Groups 4 to 8 of the periodic table is preferable. In particular, vanadium oxide, niobium oxide, tantalum oxide, chromium oxide, molybdenum oxide, tungsten oxide, manganese oxide, and rhenium oxide are preferable because of their excellent electron-accepting property. Among these, molybdenum oxide is especially preferable since it is stable in the air, has a low hygroscopic property, and is easily handled.

As the organic compound, any of a variety of compounds such as an aromatic amine compound, a carbazole derivative, an aromatic hydrocarbon, a high molecular compound (e.g., an oligomer, a dendrimer, or a polymer), and a heterocyclic compound haying a dibenzofuran skeleton or a dibenzothiophene skeleton can be used. As the organic compound used for the composite material, an organic compound having an excellent; hole-transport property is used. Specifically, a substance having a hole mobility of 10⁻⁶ cm²/Vs or higher is preferably used. However, any other substance that has a property of transporting more holes than electrons may be used.

In a composite material of the above-described transition metal oxide and the above-described organic compound, electrons in the highest occupied molecular orbital level (HOMO level) of the organic compound are transferred to the conduction band of the transition metal oxide, whereby interaction between the transition metal oxide and the organic compound, occurs. Due to this interaction, the composite material including the transition metal oxide and the organic compound has high carrier density and has conductivity.

Organic compounds that can be used for the composite material are specifically given below.

As the aromatic amine compound that can be used for the composite material, the following can be given as examples: 4,4′-[N-(1-naphthyl)-N-phenylamino]biphenyl (abbreviation: NPB); N,N′-bis(3-methylphenyl)-N,N′-diphenyl-[1,1′-biphenyl]-4,4′-diamine (abbreviation: TPD); 4,4′,4″-tris(N,N-diphehylamino)triphenylamine (abbreviation: TDATA); 4,4′,4″-tris[N-(3-methylphenyl)-N-phenylamino]triphenylamine (abbreviation: MTDATA); and N,N′-bis(spiro-9,9′-bifluoren-2-yl)-N,N′-diphenylbenzidine (abbreviation: BSPB). In addition, the following can be given: N,N′-bis(4-methylphenyl)-N,N′-diphenyl-p-phenylenediamine (abbreviation: DTDPPA); 4,4′-bis[N-(4-diphenylaminophenyl)-N-phenylamino]biphenyl (abbreviation: DPAB); N,N′-bis[4-[bis(3-methylphenyl)amino]phenyl]-N,N′-diphenyl-[1,1′-biphenyl]-4,4′-diamine (abbreviation: DNTPD); 1,3,5-tris[N-(4-diphenylaminophenyl)-N-phenylamino]benzene (abbreviation: DPA3B); 4-phenyl-4′-(9-phenylfluoren-9-yl)triphenylamine (abbreviation: BPAFLP); and 4,4′-bis[N-(9,9-dimethylfluoren-2-yl)-N-phenylamino]biphenyl (abbreviation: DFLDPBi).

As the carbazole derivative that can be used for the composite material, the following can be specifically given: 3-[N-(9-phenylcarbazol-3-yl)-N-phenylamino]-9-phenylcarbazole (abbreviation: PCzPCA1); 3,6-bis[N-(9-phenylcarbazol-3-yl)-N-phenylamino]-9-phenylcarbazole (abbreviation: PCzPCA2); and 3-[N-(1-naphthyl)-N-(9-phenylcarbazol-3-yl)amino]-9-phenylcarbazole (abbreviation: PCzPCN1).

As other examples of the carbazole derivative that can be used for the composite material, the following can be given: 4,4′-di(N-carbazolyl)biphenyl (abbreviation: CBP); 1,3,5-tris[4-(N-carbazolyl)phenyl]benzene (abbreviation: TCPB); 9-[4-(N-carbazolyl)phenyl]-10-phenylanthracene (abbreviation: CzPA); and 1,4-bis[4-(N-carbazolyl)phenyl]-2,3,5,6-tetraphenylbenzene.

As the aromatic hydrocarbon that can be used for the composite material, the following can be given, for example: 2-tert-butyl-9,10-di(2-naphthyl)anthracene (abbreviation: t-BuDNA); 2-tert-butyl-9,10-di(1-naphthyl)anthracene; 9,10-bis(3,5-diphenylphenyl)anthracene (abbreviation: DPPA); 2-tert-butyl-9,10-bis(4-phenylphenyl)anthracene (abbreviation: t-BuDBA); 9,10-di(2-naphthyl)anthracene (abbreviation: DNA); 9,10-diphenylanthracene (abbreviation: DPAnth); 2-tert-butylanthracene (abbreviation: t-BuAnth); 9,10-bis(4-methyl-1-naphthyl)anthracene (abbreviation: DMNA); 9,10-bis[2-(1-naphthyl)phenyl]-2-tert-butylanthracene; 9,10-bis[2-(1-naphthyl)phenyl]anthracene; 2,3,6,7-tetramethyl-9,10-di(1-naphthyl)anthracene; 2,3,6,7-tetramethyl-9,10-di(2-naphthyl)anthracene; 9,9′-bianthryl; 10,10′-diphenyl-9,9′-bianthryl; 10,10′-bis(2-phenylphenyl)-9,9′-bianthryl; 10,10′-bis[(2,3,4,5,6-pentaphenyl)phenyl]-9,9′-bianthryl; anthracene; tetracene; rubrene; perylene; and 2,5,8,11-tetra(tert-butyl)perylene. Besides, pentacene, coronene, or the like can also be used. In particular, the aromatic hydrocarbon which has a hole mobility of 1×10⁻⁶ cm²/Vs or higher and has 14 to 42 carbon atoms is preferable.

The aromatic hydrocarbon used for the composite material may have a vinyl skeleton. As the aromatic hydrocarbon having a vinyl group, the following can be given, for example: 4,4′-bis(2,2-diphenylvinyl)biphenyl (abbreviation: DPVBi); and 9,10-bis[4-(2,2-diphenylvinyl)phenyl]anthracene (abbreviation: DPVPA).

The organic compound used for the composite material may be a heterocyclic compound having a dibenzofuran skeleton or a dibenzothiophene skeleton.

The organic compound that can be used for the composite material may be a high molecular compound, and the following can be given as examples: poly(N-vinylcarbazole) (abbreviation: PVK); poly(4-vinyltriphenylamine) (abbreviation: PVTPA); poly[N-(4-{N′-[4-(4-diphenylamino)phenyl]phenyl-N′-phenylamino}phenyl)methacrylamide] (abbreviation: PTPDMA); and poly[N,N′-bis(4-butylphenyl)-N,N′-bis(phenyl)benzidine] (abbreviation: Poly-TPD).

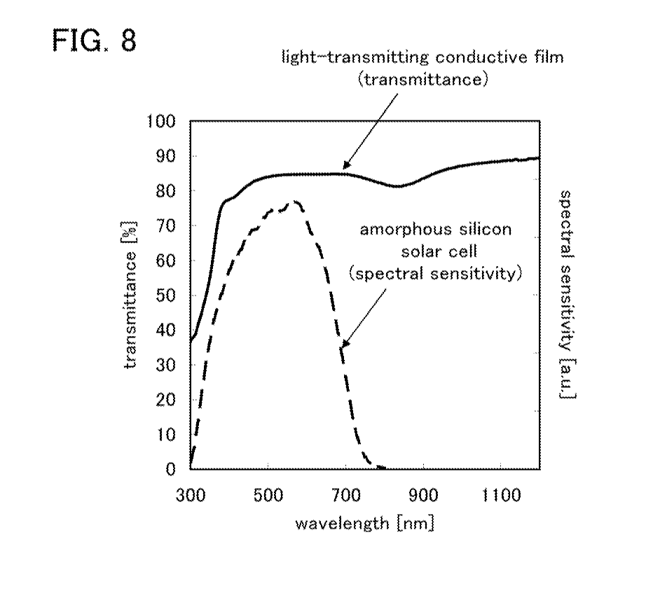

FIG. 8 shows the spectral transmittance of a light-transmitting conductive film (with a thickness of 57 nm) obtained by co-evaporation of 4-phenyl-4′-(9-phenylfluoren-9-yl)triphenylamine (abbreviation: BPAFLP) and molybdenum(VI) oxide and the spectral sensitivity characteristics of a general amorphous silicon photoelectric conversion device. As shown in FIG. 8, the light-transmitting conductive film described in this embodiment has an excellent light-transmitting property with respect to light having a wavelength range where crystalline silicon absorbs light; therefore, light reflected by a back electrode and then returned to the crystalline silicon is efficiently utilized for photoelectric conversion.

Any of a variety of methods can be employed for forming the light-transmitting conductive film, regardless of whether it is a dry process or a wet process. For a dry process, for example, a co-evaporation method in which a plurality of evaporation materials is vaporized from a plurality of evaporation sources to form a film can be used. In an example of a wet process, a composition including a composite material is adjusted by a sol-gel method, and an inkjet method, a spin coating method, or the like is used to form a film.

The use of the above-described light-transmitting conductive film for a reflection layer of a photoelectric conversion device can improve the reflectance on a back electrode side and the electric characteristics of the photoelectric conversion device.

This embodiment can be implemented in combination with any of the structures described in another embodiment as appropriate.

This application is based on Japanese Patent Application serial no. 2011-034576 filed with Japan Patent Office on Feb. 21, 2011, the entire contents of which are hereby incorporated by reference.

What is claimed is:

1. A photoelectric conversion device comprising:
a pair of electrodes;
a first silicon semiconductor layer;
a second silicon semiconductor layer in contact with the first silicon semiconductor layer;
a third silicon semiconductor layer in contact with the second silicon semiconductor layer; and
a light-transmitting film in contact with the third silicon semiconductor layer,
wherein the first, second, and third silicon semiconductor layers and the light-transmitting film are between the pair of electrodes, and
wherein the light-transmitting film includes an organic compound and an inorganic compound.

2. The photoelectric conversion device according to claim 1,
wherein the first silicon semiconductor layer has p-type conductivity, the second silicon semiconductor layer has i-type conductivity, and the third silicon semiconductor layer has n-type conductivity.

3. The photoelectric conversion device according to claim 1,
wherein the second silicon semiconductor layer is non-single-crystal, amorphous, microcrystalline, or polycrystalline.

4. The photoelectric conversion device according to claim 1,
wherein the inorganic compound is an oxide of a metal belonging to any of Groups 4 to 8 of the periodic table.

5. The photoelectric conversion device according to claim 1,
wherein the inorganic compound is selected from the group consisting of vanadium oxide, niobium oxide, tantalum oxide, chromium oxide, molybdenum oxide, tungsten oxide, manganese oxide, and rhenium oxide.

6. The photoelectric conversion device according to claim 1,
wherein the organic compound is selected from the group consisting of an aromatic amine compound, a carbazole derivative, an aromatic hydrocarbon, a high molecular compound, and a heterocyclic compound having a dibenzofuran skeleton or a dibenzothiophene skeleton.

7. The photoelectric conversion device according to claim 1,
wherein a thickness of the light-transmitting film is greater than 0 nm and less than or equal to 140 nm.

8. The photoelectric conversion device according to claim 1,
wherein one of the pair of electrodes has an uneven surface.

9. The photoelectric conversion device according to claim 1,
wherein one of the pair of electrodes is a light-transmitting conductive film.

10. The photoelectric conversion device according to claim 1,
wherein the inorganic compound has an electron-accepting property.

11. The photoelectric conversion device according to claim 1,
wherein the organic compound has a hole-transport property.

12. A photoelectric conversion device comprising:
a pair of electrodes;
a first silicon semiconductor layer;
a second silicon semiconductor layer in contact with the first silicon semiconductor layer;
a third silicon semiconductor layer in contact with the second silicon semiconductor layer;
a first light-transmitting film in contact with the third silicon semiconductor layer;
a fourth silicon semiconductor layer in contact with the first light-transmitting film;
a fifth silicon semiconductor layer in contact with the fourth silicon semiconductor layer;
a sixth silicon semiconductor layer in contact with the fifth silicon semiconductor layer; and
a second light-transmitting film in contact with the sixth silicon semiconductor layer,
wherein the first, second, third, fourth, fifth, and sixth silicon semiconductor layers, and the first and second light-transmitting films are between the pair of electrodes, and
wherein the second light-transmitting film includes an organic compound and an inorganic compound.

13. The photoelectric conversion device according to claim 12,
wherein the first silicon semiconductor layer and the fourth silicon semiconductor layer have p-type conductivity, the second silicon semiconductor layer and the fifth silicon semiconductor layer have i-type conductivity, and the third silicon semiconductor layer and the sixth silicon semiconductor layer have n-type conductivity.

14. The photoelectric conversion device according to claim 12,
wherein the second silicon semiconductor layer is amorphous, and the fourth silicon semiconductor layer is microcrystalline or polycrystalline.

15. The photoelectric conversion device according to claim 12,
wherein the inorganic compound is an oxide of a metal belonging to any of Groups 4 to 8 of the periodic table.

16. The photoelectric conversion device according to claim 12,
wherein the inorganic compound is selected from the group consisting of vanadium oxide, niobium oxide, tantalum oxide, chromium oxide, molybdenum oxide, tungsten oxide, manganese oxide, and rhenium oxide.

17. The photoelectric conversion device according to claim 12,
wherein the organic compound is selected from the group consisting of an aromatic amine compound, a carbazole derivative, an aromatic hydrocarbon, a high molecular compound, and a heterocyclic compound having a dibenzofuran skeleton or a dibenzothiophene skeleton.

18. The photoelectric conversion device according to claim 12,
wherein a thickness of the second light-transmitting film is greater than 0 nm and less than or equal to 140 nm.

19. The photoelectric conversion device according to claim 12,
wherein one of the pair of electrodes has an uneven surface.

20. The photoelectric conversion device according to claim 12,
wherein one of the pair of electrodes is a light-transmitting conductive film.

21. The photoelectric conversion device according to claim 12,
wherein the inorganic compound has an electron-accepting property.

22. The photoelectric conversion device according to claim 12,
wherein the organic compound has a hole-transport property.
